(19) United States
(12) Patent Application Publication
(10) Pub. No.: US 2014/0103927 A1
(43) Pub. Date: Apr. 17, 2014

(54) LOW-FIELD MAGNETIC RESONANCE SYSTEM (LF-MRS) FOR PRODUCING AN MRI IMAGE

(71) Applicant: Uri Rapoport, Moshav Ben Shemen (IL)

(72) Inventor: Uri Rapoport, Moshav Ben Shemen (IL)

(21) Appl. No.: 13/982,760

(22) PCT Filed: Jan. 31, 2012
(86) PCT No.: PCT/IL12/00052

§ 371 Date: Jan. 3, 2014

(30) Foreign Application Priority Data
Feb. 1, 2011 (US) 61438265

(51) Int. Cl. G01R 33/34; G01R 33/56

(52) U.S. Cl. CPC G01R 33/34015; G01R 33/5608
USPC 324/309; 324/322

(57) ABSTRACT

Low-field magnetic resonance system (LF-MRS) for producing a high-Q MRI image, said LF-MRS comprising: a. Low-field magnetic resonance device (LF-MRD); said LF-MRD is characterized by Q-value, Q_{MRD}, such that the Q-value of said LF-MRS, QMRS, is a function F₁ of said Q_{MRD}, represented by F₁(Q_{MRD}); b. a cryogenically cooled RF coil in connection with said LF-MRD; said cryogenically cooled RF coil is characterized by Q-value, Q_{RF}, c. a contrast agent (CA) adapted to be introduced into a specimen prior to the introduction of said specimen into said RF coil; The affect of said F₆ on said Q_{MRS} is significantly greater than the affect of said of predetermined function G on said Q_{MRS}, said function G is represented by either one of: G(F₁, F₂, F₃, F₄, F₅); G(F₁); G(F₂); G(F₃): G(F₄); G(F₅).

### FIELD OF THE INVENTION

The present invention relates to the field of obtaining high quality (low MRI images of a specimen using a low-field magnetic resonance system (LF-MRS).

### BACKGROUND OF THE INVENTION

Radio frequency (RF) receiving coil is an important element for the signal collection for magnetic resonance imaging (MRI) system. Quality factor (Q) of the RF receiving coil is a crucial parameter impacting the signal-to-noise ratio (SNR) and imaging quality of an MRI system. The following prior art citations are believed to represent the relevant the art in the field of MRI imaging:

U.S. Pat. No. 5,166,620 describes an NMR locking system for locking the RF frequency of the RF coil to the resonant frequency of nuclei. This prior art does not describe the inclusion of an RF frequency locking device in a LF-MRS.

U.S. Pat. No. 7,400,147 describes a magnetic resonance device (MRD) for producing an MRI image of a specimen. The main magnet described in the prior art system develops a magnetic field between the pole pieces of the main magnet without fringing fields. The prior art device does not describe including a cryogenically-cooled RF coil or using an RF frequency locking device in a LF-MRS.

US Published Patent Application No. 2010/0160173 A1 includes a description of the use of various types of magnetic contrast agents to enhance the MRI signal. This prior art article does not describe the introduction of magnetic contrast agents into a specimen to be imaged by a LF-MRS.

“Cryogenic Receive Coil and Low Noise Preamplifier for MRI at 0.01 T” by F. Resmer et al., J. of Magnetic Resonance, 203 (2010), pp 57-65, is a review article and discusses the use of various types of RF coil cooling methods in order to increase the Q-value of the RF coil. This prior art article does not describe the inclusion of a cooled RF coil in a LF-MRS. “Perspectives with Cryogenic RF Probes in Biomedical MRI” by L. Darrasse et al., Biochimie 85 (2003) pp 915-937 is a review article and discusses the use of various cryogenic RF coil cooling methods to improve the quality of an MRI image. This prior art article also does not describe the inclusion of a cooled RF coil in a LF-MRS.

The prior art describes NMR devices which use of magnetic fields typically greater than 1.0 Tessler. In these prior art devices, the sensitivity of the NMR devices is increased by increasing the intensity of the magnetic field of the main magnet. The prior art also describes the use of cryogenic cooled RF coils or magnetic contrast agents injected in a specimen or frequency locking devices for obtaining higher quality MRI images.

The current tendency in the art is to develop NMR devices with magnetic field intensity of over 1.5 Tessler, such as NMR devices with magnetic field intensities over 7 Tessler. NMR devices with high intensity magnetic fields are very expensive devices to develop, build and operate. These NMR devices with high magnetic field intensities are available at costs of approximately $3m and typically include cryogenic units for cooling the RF coil. Current low-field NMR devices cost approximately $1.25m and typically do not include cryogenic units for cooling the RF coil.

Thus, there is an unmet need in the art for providing a low cost NMR device which includes all the known features for improving and producing high quality MRI images of specimens.

### SUMMARY OF THE INVENTION

It is one object of the present invention to provide a low-field magnetic resonance system (LF-MRS) for producing a high-Q MRI image, the LF-MRS comprising: (a) a low-field magnetic resonance device (LF-MRD); the LF-MRD is characterized by Q-value, Q_{MRD}, such that the Q-value of the LF-MRS, Q_{MRS}, is a function F₁ of the Q_{MRD}, represented by F₁(Q_{MRD}); (b) a cryogenically cooled RF coil in connection with the LF-MRD; the cryogenically cooled RF coil is characterized by Q-value, Q_{RF}, such that (i) the Q_{MRS} is a function F₂ of the Q_{RF}, represented by F₂(Q_{RF}); or, (ii) the Q_{MRS} is a function F₃ of the Q_{RF} and Q_{MRD}, represented by F₃(Q_{RF}, Q_{MRS}); (c) a contrast agent (CA) adapted to be introduced into a specimen prior to the introduction of the specimen into the RF coil; such that (i) the Q_{MRS} is affected by the contrast agent according to predetermined function F₄, represented by F₄(contrast agent); (ii) the Q_{MRS} is a function F₅ of the Q_{RF} and the contrast agent, represented by F₄(Q_{RF}, contrast agent); and, (iii) the Q_{MRS} is a function F₆ of the Q_{RF}, Q_{MRD} and the contrast agent, represented by F₆(Q_{RF}, Q_{MRD}, contrast agent); wherein the affect of the F₆ on the Q_{MRS} is significantly greater than the affect of the of predetermined function G on the Q_{MRS}, the function G is represented by either one of
(i) G(F₁, F₂, F₃, F₄, F₅);
(ii) G(F₁);
(iii) G(F₂);
(iv) G(F₃);
(v) G(F₄); and,
(vi) G(F₅).

It is another object of the present invention to provide the LF-MRS as defined above, wherein the affect of the F6 is greater by at least an order of magnitude.

It is another object of the present invention to provide a low-field magnetic resonance system (LF-MRS) for producing an MRI image, the LF-MRS comprising: (a) a low-field magnetic resonance device (LF-MRD); the LF-MRD is characterized by Q-value, Q_{MRD}, such that the Signal to Noise Ratio (SNR) of the LF-MRS, SNR_{MRS}, is a function F₁ of the Q_{MRD}, represented by F₁(Q_{MRD}), (b) a cryogenically cooled RF coil in connection with the LF-MRD; the cryogenically cooled RF coil is characterized by Q-value, Q_{RF}, such that (i) the SNR_{MRS} is a function F₂ of the Q_{RF}, represented by F₂(Q_{RF}); and, (ii) the SNR_{MRS} is a function F₃ of the Q_{RF} and Q_{MRD}, represented by F3(Q_{RF}, Q_{MRS}); (c) a contrast agent adapted to be introduced into a specimen prior to the introduction of the specimen into the RF coil; such that (i) the SNR_{MRS} is affected by the contrast agent according to predetermined function F₄, represented by F₄(contrast agent); (ii) the SNR_{MRS} is a function F₅ of the Q_{RF} and the contrast agent, represented by F4(Q_{RF}, contrast agent); and, (iii) the SNR_{MRS} is a function F₆ of the Q_{RF}, Q_{MRD} and the contrast agent, represented by F₆(Q_{RF}, Q_{MRS}, contrast agent); wherein the affect of the F6 on the SNR_{MRS} is greater than the affect of the of predetermined function G on the SNR_{MRS}; the function G is represented by the function G is represented by either one of:
(i) G(F₁, F₂, F₃, F₄, F₅);
(ii) G(F₁);
(iii) G(F₂);
(iv) G(F₃);
(v) G(F₄); and,
(vi) G(F₅).

It is another object of the present invention to provide the LF-MRS as defined above, wherein the SNR_{MRS} is increased by at least 2 orders of magnitude when compared with any one of F₁, F₂, F₃, F₄, F₅ or any combination thereof.

It is another object of the present invention to provide a low-field magnetic resonance system (LF-MRS) for producing an MRI image, the LF-MRS system comprising: (a) a low-field magnetic resonance device (LF-MRD); the LF-MRD is characterized with Q-value_{LF-MRD}; and, means for generating an MRI signal; (b) a cryogenically cooled RF coil in connection with the LF-MRD; the RF coil is characterized with Q-value_{RF-Coil}; and, (c) a contrast agent adapted to be introduced into a specimen prior to the introduction of the specimen into the RF coil; the contrast agent is adapted to increase the Q-value of the LF-MRS, Q-value_{LF-MRS}; wherein the LF-MRD, the cryogenically cooled RF coil and the contrast agent increase the Q-value of the LF-MRS such that the increase is greater than the linear sum of the Q-value_{RF-Coil} increase, the Q-value_{LF-MRD} increase and the contrast agent.

It is another object of the present invention to provide the LF-MRS as defined above, further comprising a frequency locking device located in the LF-MRS for locking an RF frequency generated in the RF coil thereby locking the RF frequency to a resonant frequency of the excited nuclei.

It is another object of the present invention to provide the LF-MRS as defined above, wherein the cryogenically cooled RF coil is located in an air gap formed between magnetic pole pieces of a main magnet of the LF-MRD.

It is another object of the present invention to provide the LF-MRS as defined above, wherein the RF coil comprises at least one copper conductor the at least one copper conductor is cooled to the temperature of liquid nitrogen thereby enhancing the Q-value of the RF coil to a value of 100.

It is another object of the present invention to provide the LF-MRS as defined above, wherein the RF coil comprises at least one high temperature superconducting coil the at least one high temperature superconducting coil is cooled to a temperature of 100° K thereby enhancing the Q-value of the RF coil to a value of 1000.

It is another object of the present invention to provide the LF-MRS as defined above, wherein the RF coil comprises at least one low temperature superconducting coil the at least one low temperature superconducting coil is cooled to the temperature of liquid helium thereby enhancing the Q-value of the RF coil to a value of 10000.

It is another object of the present invention to provide the LF-MRS as defined above, wherein the magnetic contrast agent is selected from a group consisting of magnetite, maghemite, monocrystalline iron oxide nanoparticles, superparamagnetic iron oxide (SPIO) and gadolinium based compounds and any combination thereof.

It is another object of the present invention to provide the LF-MRS as defined above, wherein the cryogenically cooled RF coil is located at a predetermined distance from the LF-MRS.

It is another object of the present invention to provide the LF-MRS as defined above, wherein the predetermined distance is between 20 cm to 25 cm from the LF-MRS.

It is another object of the present invention to provide a method for producing an MRI image, the method comprises steps of: providing a low-field magnetic resonance device (LF-MRD); the LF-MRD is characterized by Q-value, Q_{MRD}, such that the Q-value of the LF-MRS, Q_{MRS}, is a function F1 of the Q_{MRD}, represented by F1 (Q_{MRD}); providing a cryogenically cooled RF coil in an air gap formed between magnetic pole pieces of a main magnet of the LF-MRD; the cryogenically cooled RF coil is characterized by Q-value, Q_{RF}, such that the Q_{MRS} is a function F2 of the Q_{RF}, represented by F2(Q_{RF}); and, the Q_{MRS} is a function F3 of the Q_{RF} and Q_{MRD}, represented by F3(Q_{RF}, Q_{MRS}); introducing a contrast agent into a specimen prior to the introduction of the specimen into the RF coil, such that the Q_{MRS} is affected by the contrast agent according to predetermined function F4, represented by F4(contrast agent); the Q_{MRS} is a function F5 of the Q_{RF} and the contrast agent, represented by F4(Q_{RF}, contrast agent); and, the Q_{MRS} is a function F6 of the Q_{RF}, Q_{MRD} and the contrast agent, represented by F6(Q_{RF}, Q_{MRS}, contrast agent); wherein the affect of the F6 on the Q_{MRS} is greater than the affect of the of predetermined function G on the Q_{MRS}, the function G is represented by either one of:
(i) G(F₁, F₂, F₃, F₄, F₅);
(ii) G(F₁);
(iii) G(F₂);
(iv) G(F₃);
(v) G(F₄); and,
(vi) G(F₅).

It is another object of the present invention to provide the method as defined above, wherein the affect of the F6 is greater by at least an order of magnitude.

It is another object of the present invention to provide the method as defined above, wherein the affect of the F6 is greater by at least two orders of magnitude.

It is another object of the present invention to provide the method as defined above, wherein the method further comprising locating a frequency locking device in the LF-MRS for locking an RF frequency generated in the RF coil thereby locking the RF frequency to a resonant frequency of the excited nuclei.

It is another object of the present invention to provide the method as defined above, further comprising step of locating the cryogenically cooled coil at a predetermined distance from the MRD.

It is another object of the present invention to provide the method as defined above, wherein the predetermined distance is between 20 cm to 25 cm from the MRD.

It is another object of the present invention to provide the method as defined above, further comprising step of cooling the RF coil to the temperature of liquid nitrogen thereby enhancing the Q-value of the RF coil to a value of 100.

It is another object of the present invention to provide the method as defined above, further comprising step of cooling the RF. coil to a temperature of 100° K thereby enhancing the Q-value of the RF coil to a value of 1000.

It is another object of the present invention to provide the method, as defined above, further comprising step of cooling the RF coil to the temperature of liquid helium thereby enhancing the Q-value of the RF coil to a value of 10000.

It is another object of the present invention to provide the method as defined above, additionally comprising step of selecting the magnetic contrast agent from a group consisting of magnetite, maghemite, monocrystalline iron oxide nanoparticles, superparamagnetic iron oxide (SPIO) and gadolinium based compounds and any combination thereof.

It is another object of the present invention to provide a method for producing an MRI image, the method comprises steps of: providing a low-field magnetic resonance device (LF-MRD); the LF-MRD is characterized by Q-value, Q_{MRD}, such that the Signal to Noise Ratio (SNR) of the LF-MRS, SNR_{MRS}, is a function F1 of the Q_{MRD}, represented by F1(Q_{MRD}); providing a cryogenically cooled RF coil in an air gap formed between magnetic pole pieces of a main magnet of the LF-MRD; the cryogenically cooled RF coil is characterized by Q-value, Q_{RF}, such that the SNR_{MRS} is a function F2 of the Q_{RF}, represented by F2(Q_{RF}); and, the SNR_{MRS} is a function F3 of the Q_{RF} and Q_{MRD}, represented by F3(Q_{RF}, Q_{MRS}); introducing a contrast agent into a specimen prior to the introduction of the specimen into the RF coil, such that the SNR_{MRS} is affected by the contrast agent according to predetermined function F4, represented by F4(contrast agent); the SNR_{MRS} is a function F5 of the Q_{RF} and the contrast agent, represented by F4(Q_{RF}, contrast agent); and, the SNR_{MRS} is a function F6 of the Q_{RF}, Q_{MRD} and the contrast agent, represented by F6(Q_{RF}, Q_{MRS}, contrast agent); wherein the affect of the F6 on the SNR_{MRS} is greater than the affect of the of predetermined function G on the SNR_{MRS}, the function G is represented by either one of:
(i) G(F₁, F₂, F₃, F₄, F₅);
(ii) G(F₁);
(iii) G(F₂);
(iv) G(F₃);
(v) G(F₄); and,
(vi) G(F₅).

It is another object of the present invention to provide the method as defined above, wherein the affect of the F6 is greater by at least an order of magnitude.

It is another object of the present invention to provide the method as defined above, wherein the affect of the F6 is greater by at least two orders of magnitude.

It is another object of the present invention to provide the method as defined above, wherein the method further comprising locating a frequency locking device in the LF-MRS for locking an RF frequency generated in the RF coil thereby locking the RF frequency to a resonant frequency of the excited nuclei.

It is another object of the present invention to provide the method as defined above, further comprising step of locating the cryogenically cooled coil at a predetermined distance from the MRD.

It is another object of the present invention to provide the method as defined above, wherein the predetermined distance is between 20 cm to 25 cm from the MRD.

It is another object of the present invention to provide the method as defined above, further comprising step of cooling the RF coil to the temperature of liquid nitrogen thereby enhancing the Q-value of the RF coil to a value of 100.

It is another object of the present invention to provide the method as defined above, further comprising step of cooling the RF. coil to a temperature of 100° K thereby enhancing the Q-value of the RF coil to a value of 1000.

It is another object of the present invention to provide the method as defined above, further comprising step of cooling the RF coil to the temperature of liquid helium thereby enhancing the Q-value of the RF coil to a value of 10000.

It is another object of the present invention to provide the method as defined above, additionally comprising step of selecting the magnetic contrast agent from a group consisting of magnetite, maghemite, monocrystalline iron oxide nanoparticles, superparamagnetic iron oxide (SPIO) and gadolinium based compounds and any combination thereof.

It is another object of the present invention to provide a method for increasing the Q-value of a low-field magnetic resonance system (LF-MRS), Q-value_{LF-MRS}, the method comprises steps of: providing a low-field magnetic resonance device (LF-MRD); the LF-MRD is characterized by Q-value, Q_{MRD}; providing a cryogenically cooled RF coil in an air gap formed between magnetic pole pieces of a main magnet of the LF-MRD; the cryogenically cooled RF coil is characterized by Q-value, Q_{RF}; introducing a contrast agent into a specimen prior to the introduction of the specimen into the RF coil; wherein the Q-value_{LF-MRS} is increased such that the increase is greater than a predetermined function G, represented by G(Q_{RF}, Q_{MRD}, contrast agent).

It is another object of the present invention to provide the method as defined above, wherein the affect of the F6 is greater by at least an order of magnitude.

It is another object of the present invention to provide the method as defined above, wherein the method further comprising locating a frequency locking device in the LF-MRS for locking an RF frequency generated in the RF coil thereby locking the RF frequency to a resonant frequency of the excited nuclei.

It is another object of the present invention to provide the method as defined above, further comprising step of locating the cryogenically cooled coil at a predetermined distance from the MRD.

It is another object of the present invention to provide the method as defined above, wherein the predetermined distance is between about to about from the MRD.

It is another object of the present invention to provide the method as defined above, further comprising step of cooling the RF coil to the temperature of liquid nitrogen thereby enhancing the Q-value of the RF coil to a value of about 100.

It is another object of the present invention to provide the method as defined above, further comprising step of cooling the RF. coil to a temperature of 100° K thereby enhancing the Q-value of the RF coil to a value of about 1000.

It is another object of the present invention to provide the method as defined above, further comprising step of cooling the RF coil to the temperature of liquid helium thereby enhancing the Q-value of the RF coil to a value of about 10000.

It is another object of the present invention to provide the method as defined above, additionally comprising step of selecting the magnetic contrast agent from a group consisting of magnetite, maghemite, monocrystalline iron oxide nanoparticles, superparamagnetic iron oxide (SPIO) and gadolinium based compounds and any combination thereof.

It is another object of the present invention to provide the a method for producing an MRI image, the method comprises: obtaining a low-field magnetic resonance device system (LF-MRS), the LF-MRS comprises: a low-field magnetic resonance device (LF-MRD), a cryogenically cooled RF coil located in an air gap formed between magnetic pole pieces of a main magnet of the LF-MRD, and adapting a contrast agent to be introduced into a specimen prior to the introduction of the specimen into the RF coil; and generating an MRI signal.

It is another object of the present invention to provide the method as defined above, wherein the method further comprising locating a frequency locking device in the LF-MRS for locking an RF frequency generated in the RF coil thereby locking the RF frequency to a resonant frequency of the excited nuclei.

It is another object of the present invention to provide the method as defined above, further comprising step of locating the cryogenically cooled coil at a predetermined distance from the MRD.

It is another object of the present invention to provide the method as defined above, wherein the predetermined distance is between about 20 cm to about 25 cm from the MRD.

It is another object of the present invention to provide the method as defined above, farther comprising step of cooling the RF coil to the temperature of liquid nitrogen thereby enhancing the Q-value of the RF coil to a value of about 100.

It is another object of the present invention to provide the method as defined above, further comprising step of cooling the RF. coil to a temperature of 100° K thereby enhancing the Q-value of the RF coil to a value of about 1000.

It is still object of the present invention to provide the method as defined above, further comprising step of cooling the RF coil to the temperature of liquid helium thereby enhancing the Q-value of the RF coil to a value of about 10000.

It is lastly an object of the present invention to provide the method as defined above, additionally comprising step of selecting the magnetic contrast agent from a group consisting of magnetite, maghemite, monocrystalline iron oxide nanoparticles, superparamagnetic iron oxide (SPIO) and gadolinium based compounds and any combination thereof.

### BRIEF DESCRIPTION OF THE DRAWINGS

A preferred embodiment of the current invention is described hereinbelow with reference to the following drawings:

FIG. 1 is a schematic drawing of a low-field magnetic resonance system (LF-MRS), in accordance with a preferred embodiment of the present invention;

FIG. 2 shows a variation of the effectiveness of the contrast agent as a function of the field intensity I, in Tessler units of the main magnet, in accordance with a preferred embodiment of the present invention; and

FIG. 3 is a schematic drawing of a LF-MRS including an RF frequency locking device, in accordance with a preferred embodiment of the present invention.

### DETAILED DESCRIPTION OF THE INVENTION

The present invention seeks to provide an MRI device for generating high quality MRI images of specimens by using an NMR device, such as low-field magnetic resonance system (LF-MRS) including a self-fastening cage magnetic resonance device (MRD), a cryogenically-cooled RF coil, an RF frequency locking device and a magnetic contrast agent introduced into a specimen. A high quality MRI image is obtained from the LF-MRS at low costs, further enhancing MRI imaging without the use of high-field intensity magnets.

The LF-MRS generates a low-field magnetic intensity of from about 0.5 to about 1.5 Tessler, without fringe fields, thus allowing the location of additional and peripheral equipment, such as the RF coil generator device, close to the main magnet without causing distortion of the magnetic field generated by the main magnet.

The term “about” used herein the present application refers to values of ±50% of the defined value.

The term “low-field” magnetic intensity used herein the present application refers to a magnetic field intensity value of approximately 1 Tessler.

The term “high-field” magnetic intensity used herein the present application refers to a magnetic field intensity value of approximately >1 Tessler.

The “Q-value” used herein defines an efficiency and quality factor of a given MRD system, such as a conventional MRD, Q_{MRD}; MRD in coupling with an RF coil and ancillary circuits, Q_{RF}; MRD in coupling with a contrast agent (Q_{CA}) located within the specimen. The overall Q value of a MRS which comprises MRD, RF and CA is preferably significantly greater (i.e., more than 2 orders of magnitude) than the individual Q values of each of the components of the MRS. According to one embodiment of the invention, Q_{MRS} is preferably significantly greater than F(Q_{MRD}, Q_{RF}, Q_{CA}); where F is a function characterized by the system and each of the components.

The present invention provides a low-field magnetic resonance system (LF-MRS) for producing an MRI image, the LF-MRS comprising:

(a) a low-field magnetic resonance device (LF-MRD); the LF-MRD is characterized by Q-value, Q_{MRD}, such that the Q-value of the LF-MRS, Q_{MRS}, is a function F1 of the Q_{MRD}, represented by F1(Q_{MRD}); (b) a cryogenically cooled RF coil, located in an air gap formed between magnetic pole pieces of a main magnet of the LF-MRD; the cryogenically cooled RF coil is characterized by Q-value, Q_{RF}, such that (i) the Q_{MRS} is a function F2 of the Q_{RF}, represented by F2(Q_{RF}); and, (ii) the Q_{MRS} is a function F3 of the Q_{RF} and Q_{MRD}, represented by F3(Q_{RF}, Q_{MRS}); (c) a contrast agent adapted to be introduced into a specimen prior to the introduction of the specimen into the RF coil; such that (i) the Q_{MRS} is affected by the contrast agent according to predetermined function F4, represented by F4(contrast agent); (ii) the Q_{MRS} is a function F5 of the Q_{RF} and the contrast agent, represented by F4(Q_{RF}, contrast agent); and, (iii) the Q_{MRS} is a function F6 of the Q_{RF}, Q_{MRD} and the contrast agent, represented by F6(Q_{RF}, Q_{MRS}, contrast agent). Wherein the affect of the F6 on the Q_{MRS} is greater than the affect of the of predetermined function G, represented by G(F1, F2, F3, F4, F5) on the Q_{MRS}.

The present invention relates to the field of obtaining high quality MRI images of specimens, typically, humans, from a LF-MRS by including in the LF-MRS a self-fastening cage magnetic resonance device (MRD), described in U.S. Pat. No. 7,400,147, assigned to the current assignee and incorporated herein by reference, a cryogenically cooled RF coil to low temperatures, an RF frequency locking device and magnetic contrast agent injected into the specimen.

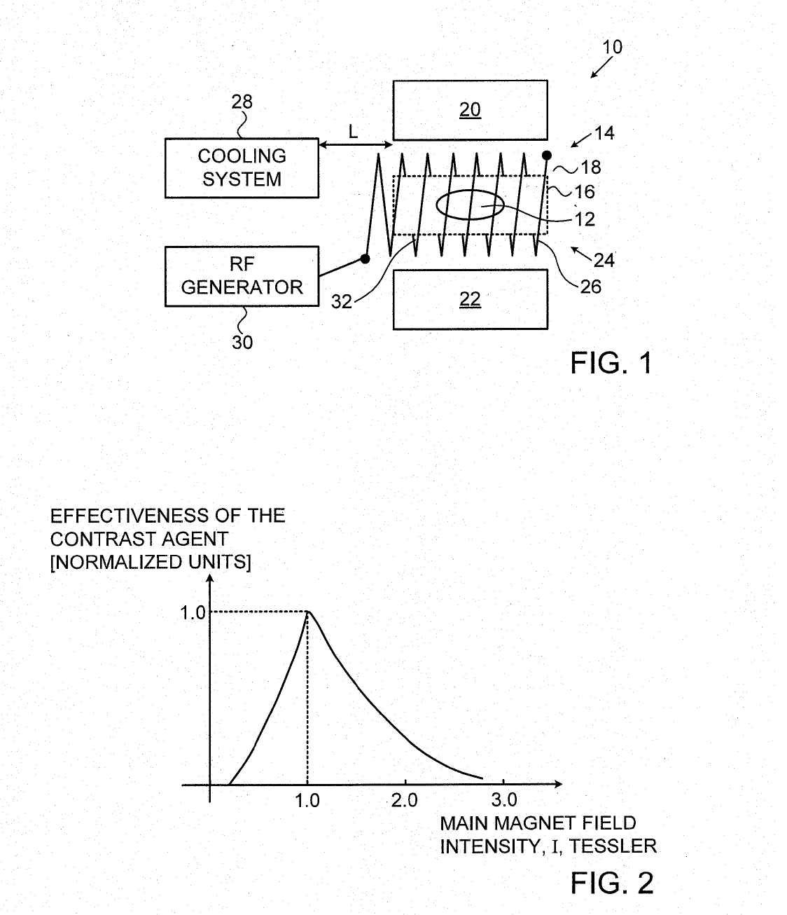

Reference is now made to FIG. 1, which schematically shows a low-field magnetic resonance system (LF-MRS) 10, in accordance with a preferred embodiment of the present invention.

The LF-MRS 10 preferably includes a self-fastening magnetic resonance device (MRD) for generating a high quality MRI image of a specimen 12, typically, a human, into whom a magnetic contrast agent has been introduced, typically intravenously, prior to the introduction of the specimen into the LF-MRS.

The magnet contrast agents, typically, include magnetite, maghemite, monocrystalline iron oxide nanoparticles, superparamagnetic iron oxide (SPIO) and gadolinium based compounds and any combination thereof.

The LF-MRS includes the MRD system 14 and the specimen 12 containing the magnetic contrast agent is located in a region of interest 16, which is located in an air gap 18 formed between the pole pieces 20 and 22 of a main magnet 24 of the LF-MRS 10. The LF-MRS 10 does not generate fringe fields, as described in U.S. Pat. No. 7,400,147 assigned to the present Assignee and incorporated herein by reference.

Thus, peripheral equipment can be located in propinquity to the main magnet 24.

Preferably, a low-field magnetic intensity of intensity values in a range of about 0.5 Tessler to about 1.5 Tessler, without fringe fields, is generated by the main magnet 14 of the LF-MRS 10.

A cryogenically-cooled RF coil 26, which is cooled by a cryogenic cooling system 28, is located in the air gap 18 and encloses the region of interest 16. An RF generator 30 applies an RF signal to the RF coil 26. The RF coil 26 generates an RF field 32 in the region of interest 16. The cryogenically cooled RF coil 26 is thermally insulated from the specimen 12, as is know in the art.

Since the LF-MRS 10 does not generate fringing fields, the RF generator 30 is located at short distance L from the main magnet 14 of the LF-MRS 10.

Typical values of L are in the range of 20 cm to 25 cm.

This is in contrast to conventional NMR devices which require the RF generator to be located at a predetermined distance from the NMR device, due to the RF generator deforming and distorting the magnetic field generated by the main magnet of the conventional NMR devices.

Reference is now made to FIG. 2, which illustrates an empirically-found variation of the effectiveness of the contrast agent as a function of the field intensity I, in Tessler units, of the main magnet 14.

FIG. 2 illustrates the maximum effectiveness of the magnetic contrast agent is achieved at a magnetic field intensity of approximately 1 Tessler.

Thus, a high quality MRI image of the specimen 12 is generated by the homogeneous, stable and uniform magnetic field of low-field magnetic intensity of approximately 1 Tessler, when the specimen 12 is injected with the magnetic contrast agent.

It is appreciated that if a metal conductor, such as copper, is used as the coil material in the RF coil 26 and the RF coil 26 is cooled to liquid nitrogen temperatures, the Q-value of the RF coil/or alternatively the Q-value of the MRI is enhanced to a value of 100.

It is also appreciated that if a high temperature superconducting coil is used for the RF coil 26 and the RF coil 26 is cooled to a temperature of approximately 100° K, the Q-value of the RF circuit is enhanced to a value of 1,000.

As know in the art the following equation is held true:

$$\frac{{SNR}_{{T}_{2}}}{{SNR}_{{T}_{1}}} = \sqrt{\frac{{Q}_{{T}_{2}} {T}_{1}}{{Q}_{{T}_{1} {T}_{2}}}}$$

The SNR of the RF coil is typically approximately 11.4 at 300° K and is typically approximately 34 when cooled to 77° K.

It is further appreciated that if a low temperature superconducting coil is used for the RF coil and the RF coil is cooled to a temperature of liquid helium, the Q-value of the RF circuit can be expected to be further substantially enhanced.

In addition to the improvements obtained in the Q-values, considerable improvements in the signal-to-noise ratio (SNR) are achieved by cryogenically cooling the RF coil 26.

By cooling the RF. coil 26 to temperatures of 77° K, an improvement in the SNR of a factor of approximately at least 3 can be achieved over the SNR factor obtained with the RF coil 26 operating at room temperatures.

It is appreciated that a further improvement in the SNR is achieved if the RF coil 26 is cooled to liquid helium temperatures.

It is further appreciated that if a low temperature superconducting coil is used for the RF coil and the RF coil is cooled to a temperature of liquid helium, the Q-value of the RF circuit is substantially enhanced to Q-values of 10,000.

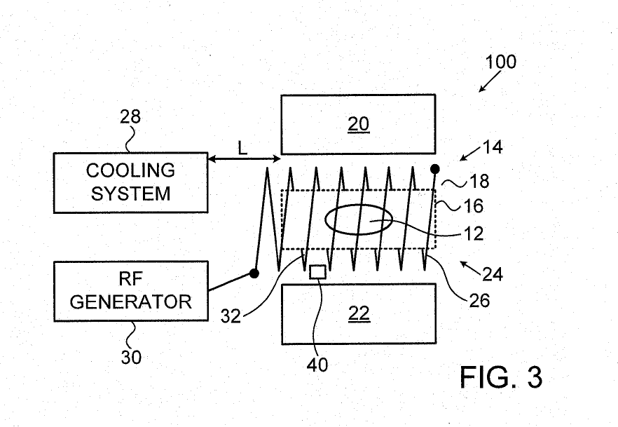

Reference is now made to FIG. 3, which schematically shows a further embodiment of the LF-MRS 100 and includes an RF frequency locking device 40. The RF frequency locking device is located in the LF-MRS 10 and locks the RF frequency generated by the RF coil 26, such that the RF frequency is locked to a resonant frequency of the excited nuclei and thereby further enhancing the high quality MRI image of the specimen 12.

Thus, it is one object of the present invention to provide a low-field magnetic resonance system (LF-MRS) for producing a high-Q MRI image, the LF-MRS comprising: (a) a low-field magnetic resonance device (LF-MRD); the LF-MRD is characterized by Q-value, Q_{MRD}, such that the Q-value of the LF-MRS, Q_{MRS}, is a function F₁ of the Q_{MRD}, represented by F₁(Q_{MRD}); (b) a cryogenically cooled RF coil in connection with the LF-MRD; the cryogenically cooled RF coil is characterized by Q-value, Q_{RF}, such that (i) the Q_{MRS} is a function F₂ of the Q_{RF}, represented by F₂(Q_{RF}); or, (ii) the Q_{MRS} is a function F₃ of the Q_{RF} and Q_{MRD}, represented by F₃(Q_{RF}, Q_{MRS}); (c) a contrast agent (CA) adapted to be introduced into a specimen prior to the introduction of the specimen into the RF coil; such that (i) the Q_{MRS} is affected by the contrast agent according to predetermined function F₄, represented by F₄(contrast agent); (ii) the Q_{MRS} is a function F₅ of the Q_{RF} and the contrast agent, represented by F₄(Q_{RF}, contrast agent); and, (iii) the Q_{MRS} is a function F₆ of the Q_{RF}, Q_{MRD} and the contrast agent, represented by F₆(Q_{RF}, Q_{MRD}, contrast agent); wherein the affect, of the F₆ on the Q_{MRS} is significantly greater than the affect of the of predetermined function G on the Q_{MRS}, the function G is represented by either one of
(i) G(F₁, F₂, F₃, F₄, F₅);
(ii) G(F₁);
(iii) G(F₂);
(iv) G(F₃);
(v) G(F₄); and,
(vi) G(F₅).

It is another object of the present invention to provide the LF-MRS as defined above, wherein the affect of the F6 is greater by at least an order of magnitude.

It is another object of the present invention to provide a low-field magnetic resonance system (LF-MRS) for producing an MRI image, the LF-MRS comprising: (a) a low-field magnetic resonance device (LF-MRD); the LF-MRD is characterized by Q-value, such that the Signal to Noise Ratio (SNR) of the LF-MRS, SNR_{MRS}, is a function F1 of the Q_{MRD}, represented by F₁(Q_{MRD}), (b) a cryogenically cooled RF coil in connection with the LF-MRD; the cryogenically cooled RF coil is characterized by Q-value, Q_{RF}, such that (i) the SNR_{MRS} is a function F₂ of the Q_{RF}, represented by F₂(Q_{RF}); and, (ii) the SNR_{MRS} is a function F₃ of the Q_{RF} and Q_{MRD}, represented by F3(Q_{RF}, Q_{MRS}); (c) a contrast agent adapted to be introduced into a specimen prior to the introduction of the specimen into the RF coil; such that (i) the SNR_{MRS} is affected by the contrast agent according to predetermined function F₄, represented by F₄(contrast agent); (ii) the SNR_{MRS} is a function F₅ of the Q_{RF} and the contrast agent, represented by F4(Q_{RF}, contrast agent); and, (iii) the SNR_{MRS} is a function F₆ of the Q_{RF}, Q_{MRD} and the contrast agent, represented by F₆(Q_{RF}, Q_{MRS}, contrast agent); wherein the affect of the F6 on the SNR_{MRS} is greater than the affect of the of predetermined function G on the SNR_{MRS}; the function G is represented by the function G is represented by either one of
(i) G(F₁, F₂, F₃, F₄, F₅);
(ii) G(F₁);
(iii) G(F₂);
(iv) G(F₃);
(v) G(F₄); and,
(vi) G(F₅).

It is another object of the present invention to provide the LF-MRS as defined above, wherein the SNR_{MRS} is increased by at least 2 orders of magnitude when compared with either one of F₁, F₂, F₃, F₄, F₅ or any combination thereof.

It is another object of the present invention to provide a low-field magnetic resonance system (LF-MRS) for producing an MRI image, the LF-MRS system comprising: (a) a low-field magnetic resonance device (LF-MRD); the LF-MRD is characterized with Q-value_{LF-MRD}; and, means for generating an MRI signal; (b) a cryogenically cooled RF coil in connection with the LF-MRD; the RF coil is characterized with Q-value_{RF-Coil}; and, (c) a contrast agent adapted to be introduced into a specimen prior to the introduction of the specimen into the RF coil; the contrast agent is adapted to increase the Q-value of the LF-MRS, Q-value_{LF-MRS}; wherein the LF-MRD, the cryogenically cooled RF coil and the contrast agent increase the Q-value of the LF-MRS such that the increase is greater than the linear sum of the Q-value_{RF-Coil} increase, the Q-value_{LF-MRD} increase and the contrast agent.

It is another object of the present invention to provide the LF-MRS as defined above, further comprising a frequency locking device located in the LF-MRS for locking an RF frequency generated in the RF coil thereby locking the RF frequency to a resonant frequency of the excited nuclei.

It is another object of the present invention to provide the LF-MRS as defined above, wherein the cryogenically cooled RF coil is located in an air gap formed between magnetic pole pieces of a main magnet of the LF-MRD.

It is another object of the present invention to provide the LF-MRS as defined above, wherein the RF coil comprises at least one copper conductor the at least one copper conductor is cooled to the temperature of liquid nitrogen thereby enhancing the Q-value of the RF coil to a value of 100.

It is another object of the present invention to provide the LF-MRS as defined above, wherein the RF coil comprises at least one high temperature superconducting coil the at least one high temperature superconducting coil is cooled to a temperature of 100° K thereby enhancing the Q-value of the RF coil to a value of 1000.

It is another object of the present invention to provide the LF-MRS as defined above, wherein the RF coil comprises at least one low temperature superconducting coil the at least one low temperature superconducting coil is cooled to the temperature of liquid helium thereby enhancing the Q-value of the RF coil to a value of 10000.

It is another object of the present invention to provide the LF-MRS as defined above, wherein the magnetic contrast agent is selected from a group consisting of magnetite, maghemite, monocrystalline iron oxide nanoparticles, superparamagnetic iron oxide (SPIO) and gadolinium based compounds and any combination thereof.

It is another object of the present invention to provide the LF-MRS as defined above, wherein the cryogenically cooled RF coil is located at a predetermined distance from the LF-MRS.

It is another object of the present invention to provide the LF-MRS as defined above, wherein the predetermined distance is between 20 cm to 25 cm from the LF-MRS.

It is another object of the present invention to provide a method for producing an MRI image, the method comprises steps of: providing a low-field magnetic resonance device (LF-MRD); the LF-MRD is characterized by Q-value, Q_{MRD}, such that the Q-value of the LF-MRS, Q_{MRS}, is a function F1 of the Q_{MRD}, represented by F1(Q_{MRD}); providing a cryogenically cooled RF coil in an air gap formed between magnetic pole pieces of a main magnet of the LF-MRD; the cryogenically cooled RF coil is characterized by Q-value, Q_{RF}, such that: the Q_{MRS} is a function F2 of the Q_{RF}, represented by F2(Q_{RF}); and, the Q_{MRS} is a function F3 of the Q_{RF} and Q_{MRD}, represented by F3(Q_{RF}, Q_{MRS}); introducing a contrast agent into a specimen prior to the introduction of the specimen into the RF coil, such that the Q_{MRS} is affected by the contrast agent according to predetermined function F4, represented by F4(contrast agent); the Q_{MRS} is a function F5 of the Q_{RF} and the contrast agent, represented by F4(Q_{RF}, contrast agent); and, the Q_{MRS} is a function F6 of the Q_{RF}, Q_{MRD} and the contrast agent, represented by F6(Q_{RF}, Q_{MRS}, contrast agent); wherein the affect of the F6 on the Q_{MRS} is greater than the affect of the of predetermined function G on the Q_{MRS}, the function G is represented by either one of
(i) G(F₁, F₂, F₃, F₄, F₅);
(ii) G(F₁);
(iii) G(F₂);
(iv) G(F₃);
(v) G(F₄); and,
(vi) G(F₅).

It is another object of the present invention to provide the method as defined above, wherein the affect of the F6 is greater by at least an order of magnitude.

It is another object of the present invention to provide the method as defined above, wherein the affect of the F6 is greater by at least two orders of magnitude.

It is another object of the present invention to provide the method as defined above, wherein the method further comprising locating a frequency locking device in the LF-MRS for locking an RF frequency generated in the RF coil thereby locking the RF frequency to a resonant frequency of the excited nuclei.

It is another object of the present invention to provide the method as defined above, further comprising step of locating the cryogenically cooled coil at a predetermined distance from the MRD.

It is another object of the present invention to provide the method as defined above, wherein the predetermined distance is between 20 cm to 25 cm from the MRD.

It is another object of the present invention to provide the method as defined above, further comprising step of cooling the RF coil to the temperature of liquid nitrogen thereby enhancing the Q-value of the RF coil to a value of 100.

It is another object of the present invention to provide the method as defined above, further comprising step of cooling the RF coil to a temperature of 100° K thereby enhancing the Q-value of the RF coil to a value of 1000.

It is another object of the present invention to provide the method as defined above, further comprising step of cooling the RF coil to the temperature of liquid helium thereby enhancing the Q-value of the RF coil to a value of 10000.

It is another object of the present invention to provide the method as defined above, additionally comprising step of selecting the magnetic contrast agent from a group consisting of magnetite, maghemite, monocrystalline iron oxide nanoparticles, superparamagnetic iron oxide (SPIO) and gadolinium based compounds and any combination thereof.

It is another object of the present invention to provide a method for producing an MRI image, the method comprises steps of: providing a low-field magnetic resonance device (LF-MRD); the LF-MRD is characterized by Q-value, Q_{MRD}, such that the Signal to Noise Ratio (SNR) of the LF-MRS, SNR_{MRS}, is a function F1 of the Q_{MRD}, represented by F1(Q_{MRD}); providing a cryogenically cooled RF coil in an air gap formed between magnetic pole pieces of a main magnet of the LF-MRD; the cryogenically cooled RF coil is characterized by Q-value, Q_{RF}, such that the SNR_{MRS} is a function F2 of the Q_{RF}, represented by F2(Q_{RF}); and, the SNR_{MRS} is a function F3 of the Q_{RF} and Q_{MRD}, represented by F3(Q_{RF}, Q_{MRS}); introducing a contrast agent into a specimen prior to the introduction of the specimen into the RF coil, such that the SNR_{MRS} is affected by the contrast agent according to predetermined function F4, represented by F4(contrast agent); the SNR_{MRS} is a function F5 of the Q_{RF} and the contrast agent, represented by F4(Q_{RF}, contrast agent); and, the SNR_{MRS} is a function F6 of the Q_{RF}, Q_{MRD} and the contrast agent, represented by F6(Q_{RF}, Q_{MRS}, contrast agent); herein the affect of the F6 on the SNR_{MRS} is greater than the affect of the of predetermined function G on the SNR_{MRS}, the function G is represented by either one of:
(i) G(F₁, F₂, F₃, F₄, F₅);
(ii) G(F₁);
(iii) G(F₂);
(iv) G(F₃);
(v) G(F₄); and,
(vi) G(F₅).

It is another object of the present invention to provide the method as defined above, wherein the affect of the F6 is greater by at least an order of magnitude.

It is another object of the present invention to provide the method as defined above, wherein the affect of the F6 is greater by at least two orders of magnitude.

It is another object of the present invention to provide the method as defined above, wherein the method further comprising locating a frequency locking device in the LF-MRS for locking an RF frequency generated in the RF coil thereby locking the RF frequency to a resonant frequency of the excited nuclei.

It is another object of the present invention to provide the method as defined above, further comprising step of locating the cryogenically cooled coil at a predetermined distance from the MRD.

It is another object of the present invention to provide the method as defined above, wherein the predetermined distance is between 20 cm to 25 cm from the MRD.

It is another object of the present invention to provide the method as defined above, further comprising step of cooling the RF coil to the temperature of liquid nitrogen thereby enhancing the Q-value of the RF coil to a value of 100.

It is another object of the present invention to provide the method as defined above, further comprising step of cooling the RF coil to a temperature of 100° K thereby enhancing the Q-value of the RF coil to a value of 1000.

It is another object of the present invention to provide the method as defined above, further comprising step of cooling the RF coil to the temperature of liquid helium thereby enhancing the Q-value of the RF coil to a value of 10000.

It is another object of the present invention to provide the method as defined above, additionally comprising step of selecting the magnetic contrast agent from a group consisting of magnetite, maghemite, monocrystalline iron oxide nanoparticles, superparamagnetic iron oxide (SPIO) and gadolinium based compounds and any combination thereof.

It is another object of the present invention to provide a method for increasing the Q-value of a low-field magnetic resonance system (LF-MRS), Q-value_{LF-MRS}, the method comprises steps of: providing a low-field magnetic resonance device (LF-MRD); the LF-MRD is characterized by Q-value, Q_{MRD}; providing a cryogenically cooled RF coil in an air gap formed between magnetic pole pieces of a main magnet of the LF-MRD; the cryogenically cooled RF coil is characterized by Q-value, Q_{RF}; introducing a contrast agent into a specimen prior to the introduction of the specimen into the RF coil;

wherein the Q-value_{LF-MRS} is increased such that the increase is greater than a predetermined function G, represented by G(Q_{RF}, Q_{MRD}, contrast agent).

It is another object of the present invention to provide the method as defined above, wherein the affect of the F6 is greater by at least an order, of magnitude.

It is another object of the present invention to provide the method as defined above, wherein the method further comprising locating a frequency locking device in the LF-MRS for locking an RF frequency generated in the RF coil thereby locking the RF frequency to a resonant frequency of the excited nuclei.

It is another object of the present invention to provide the method as defined above, further comprising step of locating the cryogenically cooled coil at a predetermined distance from the MRD.

It is another object of the present invention to provide the method as defined above, wherein the predetermined distance is between 20 cm to 25 cm from the MRD.

It is another object of the present invention to provide the method as defined above, further comprising step of cooling the RF coil to the temperature of liquid nitrogen thereby enhancing the Q-value of the RF coil to a value of 100.

It is another object of the present invention to provide the method as defined above, further comprising step of cooling the RF. coil to a temperature of 100° K thereby enhancing the Q-value of the RE coil to a value of 1000.

It is another object of the present invention to provide the method as defined above, further comprising step of cooling the RF coil to the temperature of liquid helium thereby enhancing the Q-value of the RF coil to a value of 10000.

It is another object of the present invention to provide the method as defined above, additionally comprising step of selecting the magnetic contrast agent from a group consisting of magnetite, maghemite, monocrystalline iron oxide nanoparticles, superparamagnetic iron oxide (SPIO) and gadolinium based compounds and any combination thereof.

It is another object of the present invention to provide the a method for producing an MRI image, the method comprises: obtaining a low-field magnetic resonance device system (LF-MRS), the LF-MRS comprises: a low-field magnetic resonance device (LF-MRD); a cryogenically cooled RF coil located in an air gap formed between magnetic pole pieces of a main magnet of the LF-MRD, and adapting a contrast agent to be introduced into a specimen prior to the introduction of the specimen into the RF coil; and generating an MRI signal.

It is another object of the present invention to provide the method as defined above, wherein the method further comprising locating a frequency locking device in the LF-MRS for locking an RF frequency generated in the RF coil thereby locking the RF frequency to a resonant frequency of the excited nuclei.

It is another object of the present invention to provide the method as defined above, further comprising step of locating the cryogenically cooled coil at a predetermined distance from the MRD.

It is another object of the present invention to provide the method as defined above, wherein the predetermined distance is between 20 cm to 25 cm from the MRD.

It is another object of the present invention to provide the method as defined above, further comprising step of cooling the RF coil to the temperature of liquid nitrogen thereby enhancing the Q-value of the RF coil to a value of 100.

It is another object of the present invention to provide the method as defined above, further comprising step of cooling the RF. coil to a temperature of 100° K thereby enhancing the Q-value of the RF coil to a value of 1000.

It is still object of the present invention to provide the method as defined above, further comprising step of cooling the RF coil to the temperature of liquid helium thereby enhancing the Q-value of the RF coil to a value of 10000.

It is lastly an object of the present invention to provide the method as defined above, additionally comprising step of selecting the magnetic contrast agent from a group consisting of magnetite, maghemite, monocrystalline iron oxide nanoparticles, superparamagnetic iron oxide (SPIO) and gadolinium based compounds and any combination thereof.

In the foregoing description, embodiments of the invention, including preferred embodiments, have been presented for the purpose of illustration and description. They are not intended to be exhaustive or to limit the invention to the precise form disclosed. Obvious modifications or variations are possible in light of the above teachings. The embodiments were chosen and described to provide the best illustration of the principals of the invention and its practical application, and to enable one of ordinary skill in the art to utilize the invention in various embodiments and with various modifications as are suited to the particular use contemplated. All such modifications and variations are within the scope of the invention as determined by the appended claims when interpreted in accordance with the breadth they are fairly, legally, and equitably entitled.

1-49. (canceled)

50. A low-field magnetic resonance system (LF-MRS) for producing a high-Q MRI image, said LF-MRS comprising:
a. a low-field magnetic resonance device (LF-MRD); said LF-MRD is characterized by Q-value, Q_{MRD}, such that one selected from a group consisting of the Q-value of said LF-MRS, Q_{MRS}, and the Signal to Noise Ratio (SNR) of said LF-MRS, SNR_{MRS}, is a function F₁ of said Q_{MRD}, represented by F₁(Q_{MRD});
b. a cryogenically cooled RF coil in connection with said LF-MRD; said cryogenically cooled RF coil is characterized by Q-value, Q_{RF}, such that:
i. said one selected from said group consisting of said Q_{MRS} and said SNR_{MRS} is a function F₂ of said Q_{RF}, represented by F₂(Q_{RF}); or
ii. said one selected from said group consisting of said Q_{MRS} and said SNR_{MRS} is a function F₃ of said Q_{RF} and Q_{MRD}, represented by F₃(Q_{RF}, Q_{MRS})
c. a contrast agent (CA) adapted to be introduced into a specimen prior to the introduction of said specimen into said RF coil; such that:
i. said one selected from said group consisting of said Q_{MRS} and said SNR_{MRS} is affected by said contrast agent according to predetermined function F₄, represented by F₄(contrast agent);
ii. said one selected from said group consisting of said Q_{MRS} and said SNR_{MRS} is a function F₅ of said Q_{RF} and said contrast agent, represented by F₅(QRF, contrast agent); and
iii. said one selected from said group consisting of said Q_{MRS} and said SNR_{MRS} is a function F₆ of said Q_{RF}, Q_{MRD} and said contrast agent, represented by F₆(Q_{RF}, Q_{MRD}, contrast agent)
wherein the effect of said F₆ on said one selected from said group consisting of said Q_{MRS} and said SNR_{MRS} is significantly greater than the effect of said predetermined function G on said one selected from said group consisting of said Q_{MRS} and said SNR_{MRS}, said function G is represented by any one of:
i. G(F₁, F₂, F₃, F₄, F₅);
ii. G(F₁);
iii. G(F₂);
iv. G(F₃);
v. G(F₄); and,
vi. G(F₅).

51. The LF-MRS of claim 50, wherein said effect of said F₆ is greater than G by at least an order of magnitude when compared with any one of F₁, F₂, F₃, F₄, F₅ and any combination thereof.

52. The LF-MRS of claim 50, wherein said SNR_{MRS} is increased by at least 2 orders of magnitude when compared with any one of F₁, F₂, F₃, F₄, F₅ and any combination thereof.

53. The LF-MRS according to claim 50, further comprising a frequency locking device located in said LF-MRS for locking an RF frequency generated in said RF coil thereby locking said RF frequency to a resonant frequency of the excited nuclei.

54. The LF-MRS according to claim 50, wherein said cryogenically cooled RF coil is located in an air gap formed between magnetic pole pieces of a main magnet of said LF-MRD.

55. The LF-MRS according to claim 50, wherein said RF coil comprises one of a group consisting of: at least one copper conductor said at least one copper conductor is cooled to the temperature of liquid nitrogen thereby enhancing the Q-value of said RF coil to a value of 100; at least one high temperature superconducting coil said at least one high temperature superconducting coil is cooled to a temperature of 100° K thereby enhancing the Q-value of the RF coil to a value of 1000; and at least one low temperature superconducting coil said at least one low temperature superconducting coil is cooled to the temperature of liquid helium thereby enhancing the Q-value of said RF coil to a value of 10000.

56. The LF-MRS according to claim 50, wherein said magnetic contrast agent is selected from a group consisting of magnetite, maghemite, monocrystalline iron oxide nanoparticles, superparamagnetic iron oxide (SPIO) and gadolinium based compounds and any combination thereof.

57. The LF-MRS according to claim 50, wherein said cryogenically cooled RF coil is located at a predetermined distance from said LF-MRS; said predetermined distance is between 20 cm to 25 cm from said LF-MRS.

58. A low-field magnetic resonance system (LF-MRS) for producing an MRI image, said LF-MRS system comprising:
(a) a low-field magnetic resonance device (LF-MRD); said LF-MRD is characterized with Q-valueLF-MRD; and, means for generating an MRI signal;
(b) a cryogenically cooled RF coil in connection with said LF-MRD; said RF coil is characterized with Q-valueRF-Coil; and,
(c) a contrast agent adapted to be introduced into a specimen prior to the introduction of said specimen into said RF coil; said contrast agent is adapted to increase the Q-value of said LF-MRS, Q-valueLF-MRS;
wherein said LF-MRD, said cryogenically cooled RF coil and said contrast agent increase the Q-value of said LF-MRS such that said increase is greater than the linear sum of said Q-valueRF-Coil increase, said Q-valueLF-MRD increase and said contrast agent.

59. The LF-MRS according to claim 58, further comprising a frequency locking device located in said LF-MRS for locking an RF frequency generated in said RF coil thereby locking said RF frequency to a resonant frequency of the excited nuclei.

60. The LF-MRS according to claim 58, wherein said cryogenically cooled RF coil is located in an air gap formed between magnetic pole pieces of a main magnet of said LF-MRD.

61. The LF-MRS according to claim 58, wherein said RF coil comprises one of a group consisting of: at least one copper conductor said at least one copper conductor is cooled to the temperature of liquid nitrogen thereby enhancing the Q-value of said RF coil to a value of 100; at least one high temperature superconducting coil said at least one high temperature superconducting coil is cooled to a temperature of 100° K thereby enhancing the Q-value of the RF coil to a value of 1000; and at least one low temperature superconducting coil said at least one low temperature superconducting coil is cooled to the temperature of liquid helium thereby enhancing the Q-value of said RF coil to a value of 10000.

62. The LF-MRS according to claim 58, wherein said magnetic contrast agent is selected from a group consisting of magnetite, maghemite, monocrystalline iron oxide nanoparticles, superparamagnetic iron oxide (SPIO) and gadolinium based compounds and any combination thereof.

63. The LF-MRS according to claim 58, wherein said cryogenically cooled RF coil is located at a predetermined distance from said LF-MRS; said predetermined distance is between 20 cm to 25 cm from said LF-MRS.

64. A method for producing an MRI image, said method comprises steps of:
a. providing a low-field magnetic resonance device (LF-MRD); said LF-MRD is characterized by Q-value, Q_{MRD}, such that one selected from a group consisting of the Q-value of said LF-MRS, Q_{MRS}, and the Signal to Noise Ratio (SNR) of said LF-MRS, SNR_{MRS}, is a function F₁ of said Q_{MRD}, represented by F₁(Q_{MRD});
b. providing a cryogenically cooled RF coil in an air gap formed between magnetic pole pieces of a main magnet of said LF-MRD; said cryogenically cooled RF coil is characterized by Q-value, Q_{RF}, such that:
i. said one selected from said group consisting of said Q_{MRS} and said SNR_{MRS} is a function F₂ of said Q_{RF}, represented by F₂(Q_{RF}); and,
ii. said one selected from said group consisting of said Q_{MRS} and said SNR_{MRS} is a function F₃ of said Q_{RF} and Q_{MRD}, represented by F₃(Q_{RF}, Q_{MRS});
c. introducing a contrast agent into a specimen prior to the introduction of said specimen into said RF coil, such that:
i. said one selected from said group consisting of said Q_{MRS} and said SNR_{MRS} is affected by said contrast agent according to predetermined function F₄, represented by F₄(contrast agent);
ii. said one selected from said group consisting of said Q_{MRS} and said SNR_{MRS} is a function F₅ of said Q_{RF} and said contrast agent, represented by F₅(Q_{RF}, contrast agent);
iii. said one selected from said group consisting of said Q_{MRS} and said SNR_{MRS} is a function F₆ of said Q_{RF}, Q_{MRD} and said contrast agent, represented by F₆(Q_{RF}, Q_{MRS}, contrast agent); and.
d. generating an MRI signal;
wherein the effect of said F₆ on said one selected from said group consisting of said Q_{MRS} and said SNR_{MRS} is greater than the effect of said predetermined function G on said one selected from said group consisting of said Q_{MRS} and said SNR_{MRS}, said function G is represented by any one of:
i. G(F₁, F₂, F₃, F₄, F₅);
ii. G(F₁);
iii. G(F₂);
iv. G(F₃);
v. G(F₄); and,
vi. G(F₅).

65. The method for producing an MRI image according to claim 64, wherein said effect of said F₆ is greater by at least an order of magnitude when compared with any one of F₁, F₂, F₃, F₄, F₅ or any combination thereof.

66. The method for producing an MRI image according to claim 64, wherein said effect of said F₆ is greater by at least two orders of magnitude when compared with any one of F₁, F₂, F₃, F₄, F₅ or any combination thereof.

67. The method for producing an MRI image according to claim 64, wherein said method further comprises locating a frequency locking device in said LF-MRS for locking an RF frequency generated in said RF coil thereby locking said RF frequency to a resonant frequency of the excited nuclei.

68. The method for producing an MRI image according to claim 64, further comprising a step of locating said cryogenically cooled coil at a predetermined distance from said MRD; said predetermined distance is between 20 cm to 25 cm from said MRD.

69. The method for producing an MRI image according to claim 64, further comprising a step of cooling said RF coil to a temperature selected from a group consisting of: the temperature of liquid nitrogen thereby enhancing the Q-value of said RF coil to a value of 100; a temperature of 100° K thereby enhancing the Q-value of said RF coil to a value of 1000; and the temperature of liquid helium thereby enhancing the Q-value of said RF coil to a value of 10000.

70. The method for producing an MRI image according to claim 64, additionally comprising a step of selecting said magnetic contrast agent from a group consisting of magnetite, maghemite, monocrystalline iron oxide nanoparticles, superparamagnetic iron oxide (SPIO) and gadolinium based compounds and any combination thereof.
